(19) United States
(12) Patent Application Publication
(10) Pub. No.: US 2022/0236344 A1
(43) Pub. Date: Jul. 28, 2022

(54) MAGNETIC SENSOR

(71) Applicant: SHOWA DENKO K.K., Tokyo (JP)

(72) Inventor: Tatsunori SHINO, Ichihara-shi, Chiba (JP)

(73) Assignee: SHOWA DENKO K.K., Tokyo (JP)

(21) Appl. No.: 17/609,657

(22) PCT Filed: Feb. 13, 2020
(86) PCT No.: PCT/JP2020/005449

§ 371 Date: Nov. 8, 2021

(30) Foreign Application Priority Data
May 27, 2019 (JP) 2019-098807

(51) Int. Cl. G01R 33/06; G01R 33/00; H01L 43/00

(52) U.S. Cl. CPC G01R 33/063; H01L 43/00; G01R 33/0052

(57) ABSTRACT

A magnetic sensor (1) includes: a non-magnetic substrate; and a sensitive element part (31) including plural sensitive elements (311) and (312) connected in parallel, each of the sensitive elements (311) and (312) being provided on the substrate, being composed of a soft magnetic material, having a longitudinal direction and a short direction, being provided with uniaxial magnetic anisotropy in a direction crossing the longitudinal direction, and sensing a magnetic field by a magnetic impedance effect.

### TECHNICAL FIELD

The present invention relates to a magnetic sensor.

### BACKGROUND ART

As a conventional art described in a gazette, there is a magnetic impedance effect element including a magneto-sensitive part configured with plural rectangular soft magnetic material films provided with uniaxial anisotropy (refer to Patent Document 1). In the magnetic impedance effect element, plural magneto-sensitive parts are connected in series via conductor films.

### CITATION LIST

### Patent Literature

Patent Document 1: Japanese Patent Application Laid-Open

Publication No. 2008-249406

### SUMMARY OF INVENTION

### Technical Problem

By the way, in the magnetic sensor that senses the magnetic field by the sensitive elements having the longitudinal directions and the short directions, the sensitive element having uniaxial magnetic anisotropy in the direction crossing the longitudinal direction, it is preferable to shorten the width of the sensitive element in the short direction and reduce the anisotropic magnetic field for improving the sensitivity. However, in the magnetic sensor in which the plural sensitive elements are connected in series, if the width of the sensitive element in the short direction is shortened, the impedance is increased, and thereby the sensitivity cannot be sufficiently improved in some cases.

An object of the present invention is to improve sensitivity while suppressing increase of the impedance in a magnetic sensor using a magnetic impedance effect as compared to the case where plural sensitive elements are connected in series.

### Solution to Problem

A magnetic sensor to which the present invention is applied includes: a non-magnetic substrate; and a sensitive element part including plural sensitive elements connected in parallel, each of the sensitive elements being provided on the substrate, being composed of a soft magnetic material, having a longitudinal direction and a short direction, being provided with uniaxial magnetic anisotropy in a direction crossing the longitudinal direction, and sensing a magnetic field by a magnetic impedance effect.

In addition, in such a magnetic sensor, plural sensitive element parts arranged in the short direction with an interval and windingly connected in series may be provided. In this case, it is possible to improve the sensitivity of the magnetic sensor while suppressing increase in size of the magnetic sensor in the longitudinal direction.

Further, in such a magnetic sensor, the sensitive element part may include the plural sensitive elements arranged in the short direction with an interval, a width of the sensitive element in the short direction being smaller than the interval. In this case, for example, as compared to the case in which the width of the sensitive element in the short direction is larger than an interval between the sensitive element parts, the magnetic flux can be easily gathered to the sensitive element.

Still further, in such a magnetic sensor, a thin film magnet laminated between the substrate and the sensitive element part and applying a magnetic field in the longitudinal direction of the sensitive element of the sensitive element part may be provided. In this case, it is possible to measure the change in the magnetic field with high accuracy in the vicinity of the magnetic field applied by the thin film magnet.

### Advantageous Effects of Invention

According to the present invention, it is possible to improve sensitivity while suppressing increase of the impedance in the magnetic sensor using the magnetic impedance effect as compared to the case where the plural sensitive elements are connected in series.

### BRIEF DESCRIPTION OF DRAWINGS

FIG. 1 illustrates a specific example of a magnetic sensor to which the exemplary embodiment is applied;

FIG. 2 illustrates a specific example of a magnetic sensor to which the exemplary embodiment is applied;

FIG. 3 illustrates a specific example of a magnetic sensor to which the exemplary embodiment is applied;

FIG. 4 is a diagram illustrating a relation between a magnetic field applied in the longitudinal direction of a sensitive element part in a sensitive part of the magnetic sensor and an impedance of the sensitive part;

FIG. 5 shows diagrams illustrating configurations of a sensitive part in conventional magnetic sensors;

FIG. 6 is a diagram illustrating a relation between a magnetic field applied in the longitudinal direction of a sensitive element and an impedance of the sensitive part for the conventional magnetic sensor; and

FIGS. 7A to 7E illustrate an example of a method of manufacturing the magnetic sensor.

### DESCRIPTION OF EMBODIMENTS

Hereinafter, an exemplary embodiment according to the present invention will be described with reference to attached drawings.

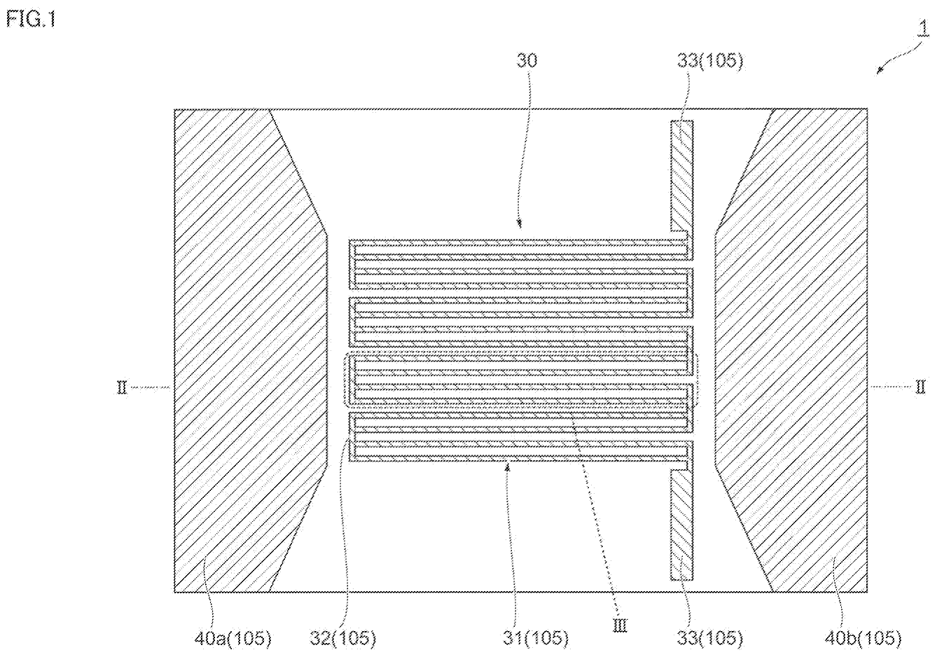

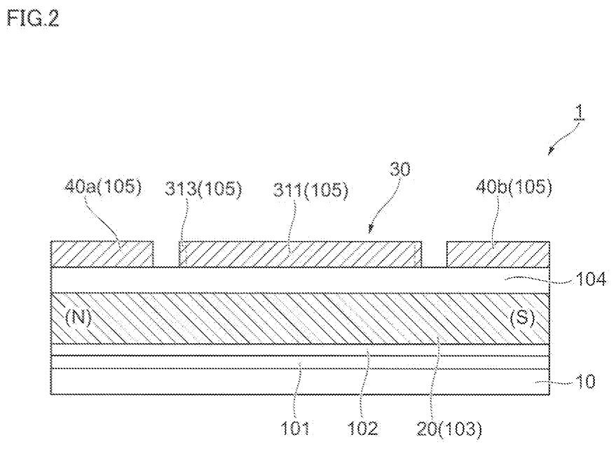

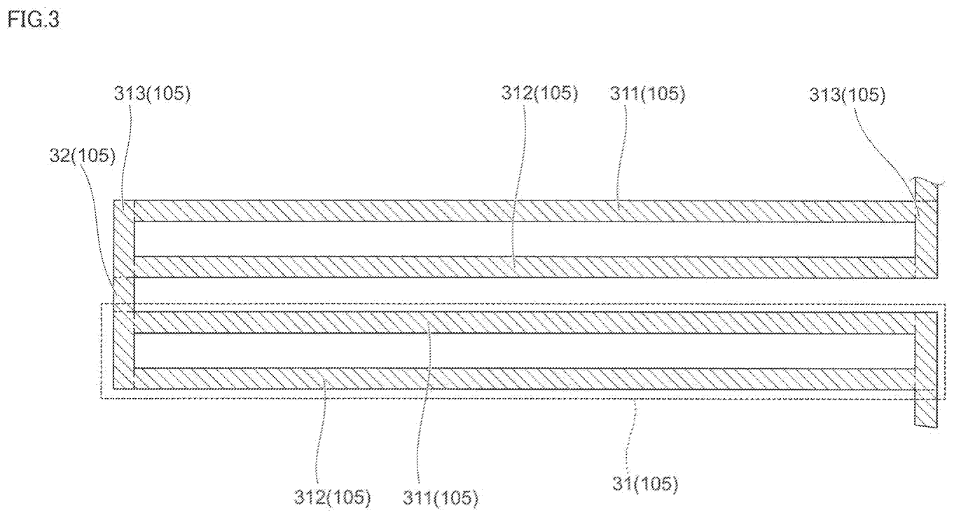

FIGS. 1 to 3 illustrate an example of a magnetic sensor 1 to which the exemplary embodiment is applied. FIG. 1 is a plan view, FIG. 2 is a cross-sectional view along the II-II line in FIG. 1, and FIG. 3 is an enlarged view of the III part in FIG. 1.

As shown in FIG. 2, the magnetic sensor 1 to which the exemplary embodiment is applied includes: a thin film magnet 20 configured with a hard magnetic material (a hard magnetic material layer 103) provided on a nonmagnetic substrate 10; and a sensitive part 30 laminated to face the thin film magnet 20 and configured with a soft magnetic material (a soft magnetic material layer 105) to sense a magnetic field. Note that a cross-sectional structure of the magnetic sensor 1 will be described in detail later.

Here, the hard magnetic material has a large, so-called coercive force, the hard magnetic material being once magnetized by an external magnetic field, even upon removal of the external magnetic field, maintaining the magnetized state. On the other hand, the soft magnetic material has a small, so-called coercive force, the soft magnetic material being easily magnetized by an external magnetic field, but, upon removal of the external magnetic field, quickly returning to a state with no magnetization or a little magnetization.

Note that, in the present specification, an element constituting the magnetic sensor 1 (the thin film magnet 20 or the like) is indicated by a two-digit number, and a layer processed into an element (the hard magnetic material layer 103 or the like) is indicated by a number of one hundreds. Then, for a figure indicating an element, a figure indicating a layer processed into the element is written in parentheses. For example, the case of the thin film magnet 20 is written as thin film magnet 20 (hard magnetic material layer 103). In the figure, the case is written as 20 (103). The same is true in other cases.

Description will be given of a planar structure of the magnetic sensor 1 by FIG. 1. The magnetic sensor 1 has a quadrangular planar shape as a specific example. Here, the sensitive part 30 and yokes 40 formed at the uppermost portion of the magnetic sensor 1 will be described. The sensitive part 30 includes: plural sensitive element parts 31; serial connection parts 32 windingly performing serial connection of the adjacent sensitive element parts 31; and terminal parts 33 connected to supply the electrical current. In the sensitive part 30 of the magnetic sensor 1 shown in FIG. 1, the eight sensitive element parts 31 are provided.

Each sensitive element part 31 includes first sensitive elements 311 and second sensitive elements 312 each having the longitudinal direction and the short direction, the first sensitive elements 311 and the second sensitive elements 312 being arranged with an interval in the short direction. In addition, each sensitive element part 31 includes parallel connection parts 313 each performing parallel connection of the first sensitive element 311 and the second sensitive element 312. Here, a horizontal direction in FIG. 1 corresponds to the longitudinal direction, and a vertical direction in FIG. 1 corresponds to the short direction.

The first sensitive element 311 and the second sensitive element 312 have, for example, the length in the longitudinal direction of 1 mm to 4 mm, the width in the short direction of 50 μm to 100 μm, and the thickness (the thickness of the soft magnetic material layer 105) of 0.5 μm to 5 μm. In addition, the interval between the first sensitive element 311 and the second sensitive element 312 in the short direction is 50 μm to 150 μm. Note that it is preferable that the widths of the first sensitive element 311 and the second sensitive element 312 in the short direction are small as compared to the interval between the first sensitive element 311 and the second sensitive element 312 in the short direction.

The parallel connection parts 313 of the sensitive element part 31 are located at both ends of the first sensitive element 311 and the second sensitive element 312 in the longitudinal direction to connect the first sensitive element 311 and the second sensitive element 312 in parallel. As shown in FIG. 3, each sensitive element part 31 is provided with two parallel connection parts 313.

Note that the sensitive element part 31 of the exemplary embodiment includes the two sensitive elements (the first sensitive element 311 and the second sensitive element 312), but three or more sensitive elements may be connected in parallel.

The serial connection part 32 is provided between end portions of the adjacent sensitive element parts 31 and windingly performs serial connection of the adjacent sensitive element parts 31. To additionally describe, the serial connection part 32 windingly performs serial connection of the sensitive element parts 31 each connecting the first sensitive elements 311 and the second sensitive elements 312 in parallel.

In the magnetic sensor 1 shown in FIG. 1, the eight sensitive element parts 31 are disposed side-by-side in parallel in the short direction, and therefore there are seven serial connection parts 32. The number of serial connection parts 32 differs depending on the number of sensitive element parts 31. For example, if there are two sensitive element parts 31, there is one serial connection part 32. In addition, if there is one sensitive element part 31, no serial connection part 32 is provided. Note that the width of the serial connection part 32 may be set in accordance with the electrical current to be applied to the sensitive part 30. In this specific example, the width of the serial connection part 32 is the same as the width of the first sensitive element 311 and the second sensitive element 312 of the sensitive element part 31 along the short direction.

The terminal parts 33 are provided to the (two) respective end portions of the sensitive element parts 31, the end portions not being connected by the serial connection parts 32. The terminal part 33 is drawn out of the end portion of the sensitive element part 31, to which an electric wire for supplying the electrical current to the sensitive part 30 is connected. Note that, in the magnetic sensor 1 shown in FIG. 1, since there are eight sensitive element parts 31, the two terminal parts 33 are provided on the right side in FIG. 1. In the case where the number of sensitive element parts 31 is an odd number, two terminal parts 33 may be divided to be provided into right and left.

Then, the sensitive element parts 31, the serial connection parts 32 and the terminal parts 33 of the sensitive part 30 are integrally constituted by a single layer of the soft magnetic material layer 105. The soft magnetic material layer 105 has conductivity, and therefore, it is possible to apply the electrical current from one terminal part 33 to the other terminal part 33.

Note that the above-described numerical values, such as the length and the width of the first sensitive element 311 and the second sensitive element 312 and the number of sensitive elements to be disposed in parallel, are merely an example; the numerical values may be changed in accordance with the value of the magnetic field to be sensed or the soft magnetic material to be used.

Further, the magnetic sensor 1 includes yokes 40 each of which is provided to face the end portions of the sensitive element parts 31 in the longitudinal direction thereof. Here, there are provided two yokes 40a and 40b, each of which is provided to face each of both end portions of the sensitive element parts 31 in the longitudinal direction thereof. Note that, in the case where the yokes 40a and 40b are not distinguished, the yokes are referred to as yokes 40. The yoke 40 guides lines of magnetic force to the end portions of the sensitive elements 31 in the longitudinal direction thereof. Therefore, the yokes 40 are constituted by a soft magnetic material (the soft magnetic material layer 105) through which the lines of magnetic force are likely to pass. In other words, the sensitive part 30 and the yokes 40 are formed of a single layer of the soft magnetic material layer 105. Note that, in the case where the lines of magnetic force sufficiently pass through in the longitudinal direction of the sensitive element parts 31 (the first sensitive elements 311 and the second sensitive elements 312), it is unnecessary to provide the yokes 40.

From above, the size of the magnetic sensor 1 is several millimeters square in the planar shape. Note that the size of the magnetic sensor 1 may be other values.

Next, with reference to FIG. 2, the cross-sectional structure of the magnetic sensor 1 will be described. The magnetic sensor 1 is configured by laminating an adhesive layer 101, a control layer 102, the hard magnetic material layer 103 (the thin film magnet 20), a dielectric layer 104 and the soft magnetic material layer 105 (the sensitive part 30 and the yokes 40) in this order on the nonmagnetic substrate 10.

The substrate 10 is composed of a non-magnetic material; for example, an oxide substrate, such as glass or sapphire, a semiconductor substrate, such as silicon, or a metal substrate, such as aluminum, stainless steel, or a nickel-phosphorus-plated metal, can be provided.

The adhesive layer 101 is a layer for improving adhesiveness of the control layer 102 to the substrate 10. As the adhesive layer 101, it is preferable to use an alloy containing Cr or Ni. Examples of the alloy containing Cr or Ni include CrTi, CrTa and NiTa. The thickness of the adhesive layer 101 is, for example, 5 nm to 50 nm. Note that, if there is no problem in adhesiveness of the control layer 102 to the substrate 10, it is unnecessary to provide the adhesive layer 101. Note that, in the present specification, composition ratios of alloys containing Cr or Ni are not shown. The same applies hereinafter.

The control layer 102 controls the magnetic anisotropy of the thin film magnet 20 constituted by the hard magnetic material layer 103 to be likely to express in the in-plane direction of the film. As the control layer 102, it is preferable to use Cr, Mo or W, or an alloy containing thereof (hereinafter, referred to as an alloy containing Cr or the like to constitute the control layer 102). Specific examples of the alloy containing Cr or the like to constitute the control layer 102 include CrTi, CrMo, CrV and CrW. The thickness of the control layer 102 is, for example, 10 nm to 300 nm.

It is preferable that the hard magnetic material layer 103 constituting the thin film magnet 20 uses an alloy that contains Co as a main component and also contains at least one of Cr and Pt or contains both of Cr and Pt (hereinafter, referred to as a Co alloy constituting the thin film magnet 20). Examples of the Co alloy constituting the thin film magnet 20 include CoCrPt, CoCrTa, CoNiCr and CoCrPtB. Note that Fe may be contained. The thickness of the hard magnetic material layer 103 is, for example, 1 μm to 3 μm.

The alloy containing Cr or the like to constitute the control layer 102 has a bcc (body-centered cubic) structure. Consequently, the hard magnetic material constituting the thin film magnet 20 (the hard magnetic material layer 103) preferably has an hcp (hexagonal close-packed) structure easily causing crystal growth on the control layer 102 composed of the alloy containing Cr or the like having the bcc structure. When crystal growth of the hard magnetic material layer 103 having the hcp structure is caused on the bcc structure, the c-axis of the hcp structure is likely to be oriented in a plane. Therefore, the thin film magnet 20 configured with the hard magnetic material layer 103 is likely to have the magnetic anisotropy in the in-plane direction. Note that the hard magnetic material layer 103 is polycrystalline composed of a set of different crystal orientations, and each crystal has the magnetic anisotropy in the in-plane direction. The magnetic anisotropy is derived from crystal magnetic anisotropy.

Note that, to promote the crystal growth of the alloy containing Cr or the like to constitute the control layer 102 and the Co alloy constituting the thin film magnet 20, the substrate 10 may be heated to 100° C. to 600° C. By the heating, the crystal growth of the alloy containing Cr or the like constituting the control layer 102 is likely to be caused, and thereby crystalline orientation is likely to be provided so that the hard magnetic material layer 103 having the hcp structure includes an axis of easy magnetization in a plane. In other words, the magnetic anisotropy is likely to be imparted in a plane of the hard magnetic material layer 103.

The dielectric layer 104 is configured with a nonmagnetic dielectric material and electrically insulates the thin film magnet 20 and the sensitive part 30. Specific examples of the dielectric material constituting the dielectric layer 104 include oxide, such as SiO₂, Al₂O₃, or TiO₂, or nitride, such as Si₂N₄ or AlN. In addition, the thickness of the dielectric layer 104 is, for example, 0.1 μm to 30 μm.

Each of the first sensitive element 311 and the second sensitive element 312 in the sensitive element part 31 of the sensitive part 30 is provided with uniaxial magnetic anisotropy in a direction crossing the longitudinal direction, for example, the short direction intersecting the longitudinal direction (in other words, the width direction of the first sensitive element 311 and the second sensitive element 312). Note that the direction crossing the longitudinal direction may have an angle exceeding 45° with respect to the longitudinal direction.

As the soft magnetic material layer 105 constituting the sensitive part 30, it is preferable to use an amorphous alloy, which is an alloy containing Co as a main component doped with a high melting point metal, such as Nb, Ta or W (hereinafter, referred to as a Co alloy constituting the sensitive part 30). Specific examples of the Co alloy constituting the sensitive part 30 include CoNbZr, CoFeTa and CoWZr.

The adhesive layer 101, the control layer 102, the hard magnetic material layer 103 and the dielectric layer 104 are processed to have a quadrangular planar shape (refer to FIG. 1). Then, of the exposed side surfaces, in the two facing side surfaces, the thin film magnet 20 serves as the north pole ((N) in FIG. 2) and the south pole ((S) in FIG. 2). Note that the line connecting the north pole and the south pole of the thin film magnet 20 takes the longitudinal direction of the first sensitive element 311 and the second sensitive element 312 in the sensitive element part 31 of the sensitive part 30. Here, to take the longitudinal direction means that an angle formed by the line connecting the north pole and the south pole and the longitudinal direction is less than 45°. Note that the smaller the angle formed by the line connecting the north pole and the south pole and the longitudinal direction, the better.

In the magnetic sensor 1, the lines of magnetic force outputted from the north pole of the thin film magnet 20 once go to the outside of the magnetic sensor 1. Then, a part of the lines of magnetic force passes through the first sensitive elements 311 and the second sensitive elements 312 of the sensitive element part 31 via the yoke 40a and goes to the outside again via the yoke 40b. The lines of magnetic force that have passed through the first sensitive elements 311 and the second sensitive elements 312 return to the south pole of the thin film magnet 20 together with the lines of magnetic force that have not passed through the first sensitive elements 311 and the second sensitive elements 312. In other words, the thin film magnet 20 applies the magnetic field (the bias magnetic field Hb to be described later) to the longitudinal direction of the first sensitive element 311 and the second sensitive element 312 in the sensitive element part 31.

Note that the north pole and the south pole of the thin film magnet 20 are collectively referred to as both magnetic poles, and when the north pole and the south pole are not distinguished, they are referred to as a magnetic pole.

Note that, as shown in FIG. 1, the yoke 40 (the yokes 40a and 40b) is configured so that the shape thereof as viewed from the front surface side of the substrate 10 is narrowed as approaching the sensitive part 30. This is to concentrate the magnetic field to (to gather the lines of magnetic force on) the sensitive part 30. In other words, the magnetic field in the sensitive part 30 is strengthened to further improve the sensitivity. Note that the width of the portion of the yoke 40 (the yokes 40a and 40b) facing the sensitive part 30 may not be narrowed.

Here, the interval between the yoke 40 (the yokes 40a and 40b) and the sensitive parts 30 may be, for example, 1 μm to 100 μm.

### (Action of Magnetic Sensor 1)

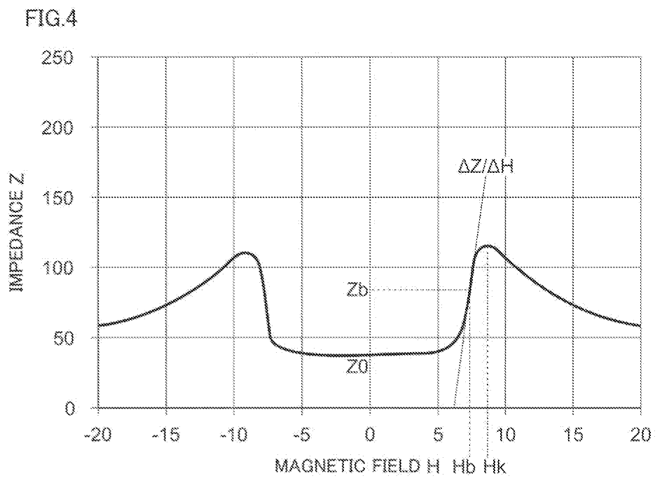

Subsequently, action of the magnetic sensor 1 in the exemplary embodiment will be described. FIG. 4 is a diagram illustrating a relation between the magnetic field applied in the longitudinal direction of the sensitive element parts 31 in the sensitive part 30 of the magnetic sensor 1 and the impedance of the sensitive part 30. In FIG. 4, the horizontal axis indicates the magnetic field H, and the vertical axis indicates the impedance Z. The impedance Z of the sensitive part 30 is measured by passing a high-frequency current between two terminal parts 33.

Note that, in the magnetic sensor 1 with the characteristics shown in FIG. 4, the sensitive part 30 and the yokes 40 are configured with the soft magnetic material layer 105 composed of Co₈₅Nb₁₂Zr₃ with a thickness of 1.5 μm. In addition, the first sensitive element 311 and the second sensitive element 312 of the sensitive element part 31 have the width of 50 μm and the length of 3 mm. Also, the interval between the first sensitive element 311 and the second sensitive element 312 in the sensitive element part 31, and the interval between the first sensitive element 311 and the second sensitive element 312 between the adjacent sensitive element parts 31, is 75 μm. Further, both the serial connection part 32 and the parallel connection part 313 of the sensitive element part 31 have a width of 50 μm.

Moreover, FIG. 4 shows the result measured by passing the high-frequency current of 100 MHz between the terminal parts 33 of the sensitive part 30.

As shown in FIG. 4, the impedance Z of the sensitive part 30 is changed, increased or decreased, as the absolute value of the magnetic field H increases in the positive direction or the negative direction, with a boundary of the magnetic field H being 0 (H=0). Moreover, the amount of change in the impedance Z (in other words, the slope of the graph) in relation to the change in the magnetic field H depends on the magnitude of magnetic field H.

Consequently, by use of a portion where the amount of change ΔZ in the impedance Z with respect to the amount of change ΔH in the magnetic field H to be applied is steep (in other words, the portion where ΔZ/ΔH is large), it is possible to extract extremely weak change in the magnetic field H as the amount of change ΔZ in the impedance Z. In FIG. 4, the magnetic field H, where the amount of change ΔZ of the impedance to the amount of change ΔH of the magnetic field H (ΔZ/ΔH) is the maximum, is shown as the magnetic field Hb. In the magnetic sensor 1, it is possible to measure the amount of change ΔH of the magnetic field H in the vicinity of the magnetic field Hb with high accuracy. The magnetic field Hb is referred to as a bias magnetic field in some cases.

Note that, in the following description, ΔZ/ΔH, which is the slope of the graph in the magnetic field Hb (in other words, the maximum ΔZ/ΔH), is referred to as Sₘₐₓ in some cases. In addition, in some cases, the impedance Z in the magnetic field Hb is referred to as the impedance Zb, and the impedance in the case where the magnetic field H is not applied (H=0) is referred to as the impedance Z0. Further, the magnetic field H, where the impedance Z takes the maximum value, is sometimes referred to as an anisotropic magnetic field Hk.

It can be said that the sensitivity of the magnetic sensor 1 measuring the amount of change ΔH in the magnetic field H based on the relation between the magnetic field H and the impedance Z is favorable as the value of Sₘₐₓ/Zb is larger. Therefore, to increase the sensitivity of the magnetic sensor 1, it is preferable to increase Sₘₐₓ or decrease the impedance Zb.

Here, in the magnetic sensor 1, according to the relation between the magnetic field H and the impedance Z shown in FIG. 4, there is a tendency that, by reducing the anisotropic magnetic field Hk without changing the maximum value of the impedance Z, the amount of change ΔZ in the impedance Z becomes steep and Sₘₐₓ is increased.

In general, the sensitive element with the longitudinal direction and the short direction, the short direction being provided with uniaxial magnetic anisotropy, has magnetic shape anisotropy, which arises from the shape of the sensitive element, in the longitudinal direction. Then, as the length of the sensitive element in the short direction (hereinafter, referred to as the width of the sensitive element in some cases) is small, the magnetic shape anisotropy in the longitudinal direction is increased. In other words, as the width of the sensitive element is reduced, the anisotropic magnetic field Hk becomes smaller and Sₘₐₓ becomes larger.

However, in a conventional magnetic sensor in which plural sensitive elements are windingly and serially connected, by simply reducing the width of each sensitive element, while the anisotropic magnetic field Hk is reduced and Sₘₐₓ is increased, the resistance value of each sensitive element rises and the impedance Zb in the magnetic field Hb is increased. In this case, it becomes difficult to sufficiently increase Sₘₐₓ/Zb, and thereby desired sensitivity sometimes cannot be obtained in the magnetic sensor.

In contrast thereto, as described above, in the magnetic sensor 1 of the exemplary embodiment, the sensitive element part 31 of the sensitive part 30 has a configuration in which the first sensitive elements 311 and the second sensitive elements 312 are connected in parallel. This makes it possible for the magnetic sensor 1 of the exemplary embodiment to decrease the anisotropic magnetic field Hk and increase Sₘₐₓ while suppressing the rise of the impedance Zb in the magnetic field Hb by, for example, adjusting the widths of the first sensitive element 311 and the second sensitive element 312. Consequently, the sensitivity of the magnetic sensor 1 can be improved.

Subsequently, action of the magnetic sensor 1 of the exemplary embodiment will be described in more detail as compared to the conventional magnetic sensor in which the plural sensitive elements are windingly and serially connected.

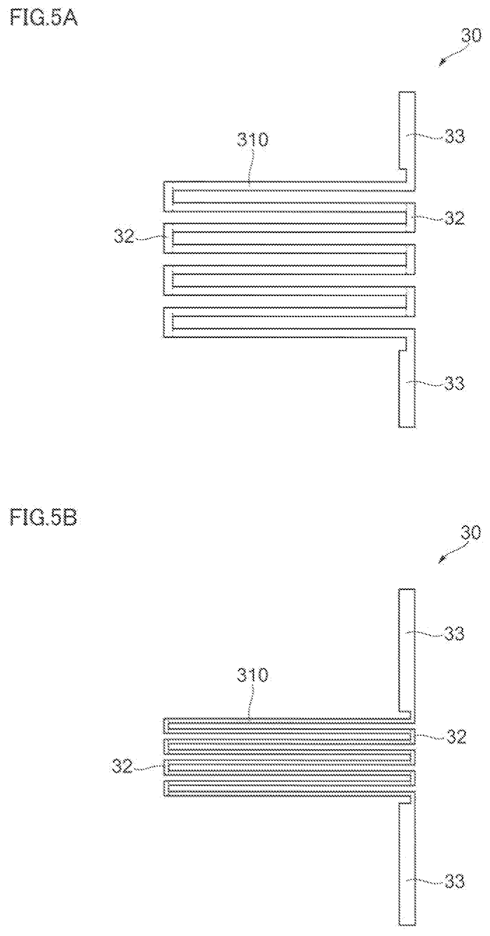

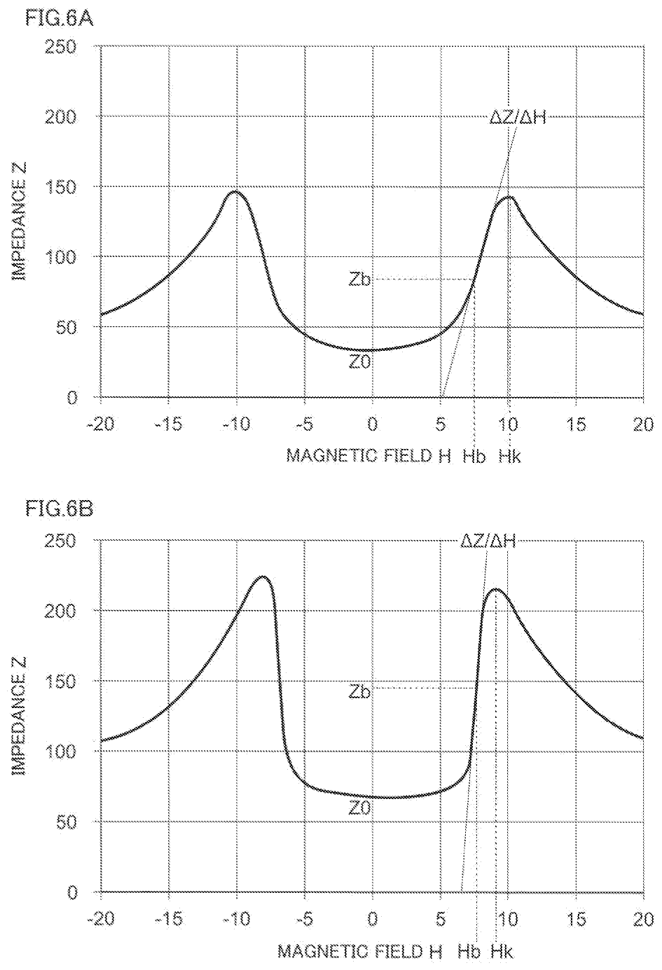

FIGS. 5A and 5B are diagrams illustrating configurations of the sensitive parts 30 in conventional magnetic sensors. In FIGS. 5A and 5B, the same reference signs are used for the same configurations as the magnetic sensor 1 of the exemplary embodiment shown in FIGS. 1 to 3. In addition, FIGS. 6A and 6B illustrate, for the conventional magnetic sensors with the sensitive parts 30 having the structures shown in FIGS. 5A and 5B, respectively, the relations between the magnetic field applied in the longitudinal direction of the sensitive element 310, which will be described later, and the impedance of the sensitive part 30. In FIGS. 6A and 6B, the horizontal axis indicates the magnetic field H, and the vertical axis indicates the impedance Z. In addition, in the following description, a conventional magnetic sensor, which includes the sensitive part 30 shown in FIG. 5A and whose property is shown in FIG. 6A, is referred to as a conventional magnetic sensor A. Similarly, a conventional magnetic sensor, which includes the sensitive part 30 shown in FIG. 5B and whose property is shown in FIG. 6B, is referred to as a conventional magnetic sensor B.

As shown in FIGS. 5A and 5B, the sensitive part 30 of the conventional magnetic sensors A and B includes: plural (in these examples, eight) sensitive elements 310; plural (in these examples, seven) serial connection parts 32 that windingly perform serial connection of the plural sensitive elements 310; and the terminal parts 33.

Here, in the magnetic sensor A, the width of the sensitive element 310 and the serial connection part 32 of the sensitive part 30 is 100 μm, and the interval between the sensitive elements 310 is 150 μm. In addition, in the magnetic sensor B, the width of the sensitive element 310 and the serial connection part 32 of the sensitive part 30 is 50 μm, and the interval between the sensitive elements 310 is 75 μm. Note that the conventional magnetic sensors A and B include the same configuration as the magnetic sensor 1 of the exemplary embodiment having the property shown in FIG. 4, except for the shape of the sensitive part 30.

Table 1 shows values of the anisotropic magnetic field Hk, the impedance Z0, the impedance Zb, Sₘₐₓ (=AZ/AH) and Sₘₐₓ/Zb in each graph shown in FIGS. 4, 6A and 6B, for the magnetic sensor 1 of the exemplary embodiment and the conventional magnetic sensors A and B.

TABLE 1

| | Width of | Hk | Z0 | Zb | Sₘₐₓ | Sₘₐₓ/Zb |
|---|---|---|---|---|---|---|
| | sensitive element | (Oe) | (Ω) | (Ω) | (Ω/Oe) | (%/Oe) |
| Magnetic | 50 μm × 2 | 8.8 | 36 | 76.9 | 88 | 115 |
| sensor 1 | (parallel) | | | | | |
| Magnetic | 100 μm | 10.1 | 32 | 111.5 | 74 | 66 |
| sensor A | | | | | | |
| Magnetic | 50 μm | 8.6 | 66 | 145.4 | 174 | 120 |
| sensor B | | | | | | |

As shown in Table 1, in the magnetic sensor 1 of the exemplary embodiment, in which the first sensitive elements 311 and the second sensitive elements 312 with the width of 50 μm are connected in parallel, the anisotropic magnetic field Hk is reduced as compared to the conventional magnetic sensor A, in which the sensitive elements 310 with the width of 100 μm are connected in series. To additionally describe, in the magnetic sensor 1 of the exemplary embodiment and the conventional magnetic sensor A, irrespective of the equal sum of the widths in the short direction of the sensitive elements (the first sensitive element 311, the second sensitive element 312, and the sensitive element 310) constituting the sensitive part 30, the anisotropic magnetic field Hk in the magnetic sensor 1 of the exemplary embodiment is reduced as compared to the conventional magnetic sensor A. As a result, in the magnetic sensor 1 of the exemplary embodiment, Sₘₐₓ rises and Sₘₐₓ/Zb is improved, as compared to the conventional magnetic sensor A.

In other words, the magnetic sensor 1 of the exemplary embodiment has the configuration, in which the plural sensitive elements (the first sensitive elements 311 and the second sensitive elements 312) are connected in parallel; consequently, the sensitivity can be improved.

In addition, as shown in Table 1, in the magnetic sensor 1 of the exemplary embodiment, in which the first sensitive elements 311 and the second sensitive elements 312 with the width of 50 μm are connected in parallel, the impedances Zb and Z0 are reduced as compared to the conventional magnetic sensor B, in which the sensitive elements 310 with the width of 50 μm are connected in series. To additionally describe, in the magnetic sensor 1 of the exemplary embodiment and the conventional magnetic sensor B, irrespective of the equal widths in the short direction of each sensitive element (the first sensitive element 311, the second sensitive element 312, and the sensitive element 310), the impedances Zb and Z0 in the magnetic sensor 1 of the exemplary embodiment is reduced as compared to the conventional magnetic sensor B.

On the other hand, the anisotropic magnetic field Hk of the magnetic sensor 1 of the exemplary embodiment is at the same level as that of the conventional magnetic sensor B, and the sensitivity of the magnetic sensor 1 (Sₘₐₓ/Zb) is also at the same level as that of the conventional magnetic sensor B.

In other words, in the magnetic sensor 1 of the exemplary embodiment, it is possible to set the impedances Zb and Z0 within desired ranges while suppressing decrease of the sensitivity (Sₘₐₓ/Zb) by adjusting the widths of the first sensitive element 311 and the second sensitive element 312 in the short direction.

In general, in a detection circuit detecting changes in the magnetic field by use of the magnetic sensor 1, there are preferable ranges for the impedances Zb and Z0 due to differences in the circuit configuration and the like. In the exemplary embodiment, it is possible to realize the magnetic sensor 1 tailored to the circuit configuration, etc., of the detection circuit by adjusting the widths of the first sensitive element 311 and the second sensitive element 312 in the short direction.

Here, in the magnetic sensor 1 of the exemplary embodiment, as compared to the width of the first sensitive element 311 and the second sensitive element 312, the interval between the adjacent first sensitive element 311 and second sensitive element 312 is large. Consequently, for example, as compared to the case in which the interval between the adjacent first sensitive element 311 and second sensitive element 312 is smaller than the width of the first sensitive element 311 and the second sensitive element 312, the magnetic flux can be easily gathered to each first sensitive element 311 and each second sensitive element 312. This can further improve the sensitivity of the magnetic sensor 1.

### (Method of Manufacturing Magnetic Sensor 1)

Next, an example of a method of manufacturing the magnetic sensor 1 will be described.

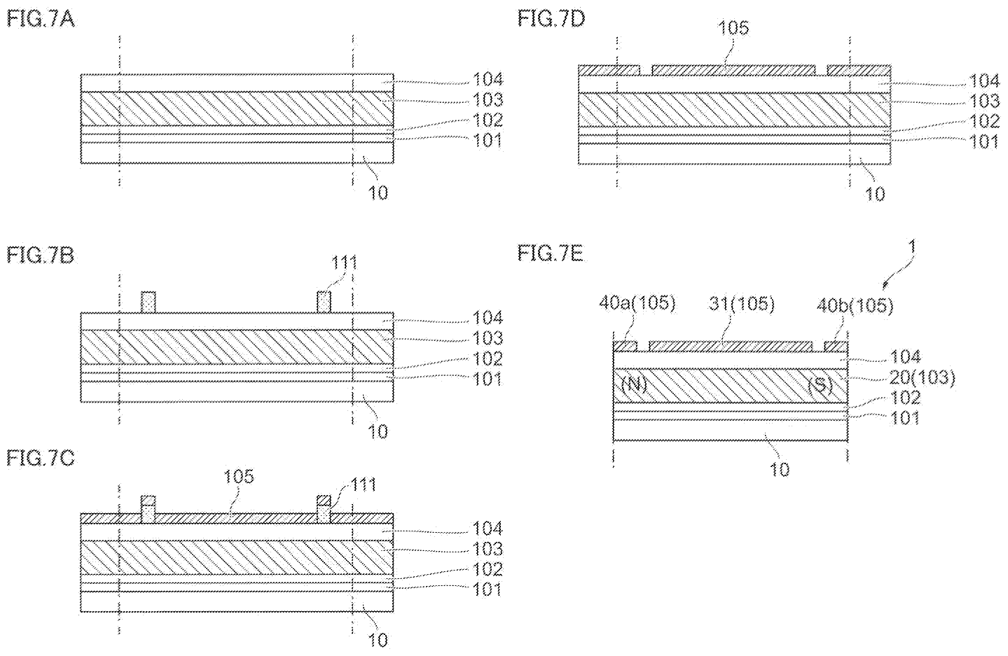

FIGS. 7A to 7E illustrate the specific example of the method of manufacturing the magnetic sensor 1. FIGS. 7A to 7E show respective processes in the method of manufacturing the magnetic sensor 1. The processes proceed in the order of FIGS. 7A to 7E. FIGS. 7A to 7E show representative processes, and other processes may be included. The processes proceed in the order of FIGS. 7A to 7E. FIGS. 7A to 7E correspond to the cross-sectional view cut along the II-II line in FIG. 1 shown in FIG. 2.

As described above, the substrate 10 is composed of a non-magnetic material; for example, an oxide substrate, such as glass or sapphire, a semiconductor substrate, such as silicon, or a metal substrate, such as aluminum, stainless steel, or a nickel-phosphorus-plated metal, can be provided. On the substrate 10, for example, streaky grooves or streaky asperities with the radius of curvature Ra of 0.1 nm to 100 nm may be provided by use of a polisher or the like. Note that it is preferable to provide the streaks of the streaky grooves or the streaky asperities in a direction connecting the north pole and the south pole of the thin film magnet 20 configured with the hard magnetic material layer 103. By doing so, the crystal growth in the hard magnetic material layer 103 is promoted in the direction of the grooves. Consequently, the axis of easy magnetization of the thin film magnet 20 configured with the hard magnetic material layer 103 is more likely to face the groove direction (the direction connecting the north pole and the south pole of the thin film magnet 20). In other words, magnetization of the thin film magnet 20 is made easier.

Here, as an example, the substrate 10 will be described as glass having a diameter of about 95 mm and a thickness of about 0.5 mm. In the case where the planar shape of the magnetic sensor 1 is several millimeters square, plural magnetic sensors 1 are collectively manufactured on the substrate 10, and thereafter, divided (cut) into individual magnetic sensors 1. In FIGS. 7A to 7E, attention is focused on one magnetic sensor 1 depicted at the center, and a part of each of the adjacent magnetic sensors 1 on the right and left sides is also shown. Note that the border between the adjacent magnetic sensors 1 is indicated by a long-dot-and-dash line.

As shown in FIG. 7A, after washing the substrate 10, on one of the surfaces (hereinafter, referred to as a front surface) of the substrate 10, the adhesive layer 101, the control layer 102, the hard magnetic material layer 103 and the dielectric layer 104 are deposited (accumulated) in order, to thereby form a laminated body.

First, the adhesive layer 101 that is an alloy containing Cr or Ni, the control layer 102 that is an alloy containing Cr and the like, the hard magnetic material layer 103 that is a Co alloy constituting the thin film magnet 20 are continuously deposited (accumulated) in order. The deposition can be performed by a sputtering method or the like. The substrate 10 is moved to face plural targets formed of respective materials in order, and thereby the adhesive layer 101, the control layer 102 and the hard magnetic material layer 103 are laminated on the substrate 10 in order. As described above, in forming the control layer 102 and the hard magnetic material layer 103, the substrate 10 may be heated to, for example, 100° C. to 600° C. for accelerating the crystal growth.

Note that, in deposition of the adhesive layer 101, the substrate 10 may be heated or may not be heated. To remove the moisture and so forth absorbed onto the surface of the substrate 10, the substrate 10 may be heated before the adhesive layer 101 is deposited.

Next, the dielectric layer 104, which is oxide, such as SiO₂, Al₂O₃, or TiO₂, or nitride, such as Si₂N₄ or AlN is deposited (accumulated). Deposition of the dielectric layer 104 can be performed by a plasma CVD method, a reactive sputtering method or the like.

Then, as shown in FIG. 7B, a pattern by photoresist (a resist pattern) 111, which has an opening serving as a portion where the sensitive part 30 and the yokes 40 (the yokes 40a and 40b) are formed, is formed by a publicly known photolithography technique.

Then, as shown in FIG. 7C, the soft magnetic material layer 105 that is a Co alloy constituting the sensitive part 30 is deposited (accumulated). The deposition of the soft magnetic material layer 105 can be performed by using, for example, the sputtering method.

As shown in FIG. 7D, the resist pattern 111 is removed, and the soft magnetic material layer 105 on the resist pattern 111 is also removed (lifted-off). Consequently, the sensitive part 30 and the yokes 40 (the yoke 40a and 40b) constituted by the soft magnetic material layer 105 are formed. In other words, the sensitive part 30 and the yokes 40 are formed by a single deposition of the soft magnetic material layer 105.

Thereafter, the uniaxial magnetic anisotropy is imparted to the soft magnetic material layer 105 in the width direction of the first sensitive element 311 and the second sensitive element 312 (for both, refer to FIG. 3) in the sensitive element part 31 of the sensitive part 30. The impartation of the uniaxial magnetic anisotropy to the soft magnetic material layer 105 can be performed by heat treatment at 400° C. in a rotating magnetic field of, for example, 3 kG (0.3 T) (heat treatment in the rotating magnetic field) and by heat treatment at 400° C. in a static magnetic field of 3 kG (0.3 T) (heat treatment in the static magnetic field) subsequent thereto. At this time, the soft magnetic material layer 105 constituting the yokes 40 is provided with the similar uniaxial magnetic anisotropy. However, the yokes 40 just have to play a role of a magnetic circuit and may not be provided with the uniaxial magnetic anisotropy.

Next, the hard magnetic material layer 103 constituting the thin film magnet 20 is magnetized. Magnetizing of the hard magnetic material layer 103 can be performed by, in the static magnetic field or in a pulsed magnetic field, continuously applying a magnetic field larger than a coercive force of the hard magnetic material layer 103 until magnetization of the hard magnetic material layer 103 becomes saturated.

Thereafter, as shown in FIG. 7E, the plural magnetic sensors 1 formed on the substrate 10 is divided (cut) into the individual magnetic sensors 1. In other words, as shown in the plan view of FIG. 1, the substrate 10, the adhesive layer 101, the control layer 102, the hard magnetic material layer 103, the dielectric layer 104 and the soft magnetic material layer 105 are cut to have a quadrangular planar shape. Then, on the side surfaces of the hard magnetic material layer 103 that has been divided (cut), magnetic poles (the north pole and the south pole) of the thin film magnet 20 are exposed. Thus, the magnetized hard magnetic material layer 103 serves as the thin film magnet 20. The division (cutting) can be performed by a dicing method, a laser cutting method or the like.

Note that, before the process of dividing the plural magnetic sensors 1 into the individual magnetic sensors 1 shown in FIG. 7E, the adhesive layer 101, the control layer 102, the hard magnetic material layer 103, the dielectric layer 104, and the soft magnetic material layer 105 between the adjacent magnetic sensors 1 on the substrate 10 may be removed by etching so that the planar shape of the magnetic sensor 1 is quadrangular (the planar shape of the magnetic sensor 1 shown in FIG. 1). Then, the exposed substrate 10 may be divided (cut).

Moreover, after the process of forming the laminated body shown in FIG. 7A, the adhesive layer 101, the control layer 102, the hard magnetic material layer 103 and the dielectric layer 104 may be processed so that the planar shape of the magnetic sensor 1 is quadrangular (the planar shape of the magnetic sensor 1 shown in FIG. 1).

Note that the processes in the manufacturing method shown in FIGS. 7A to 7E are simplified as compared to these manufacturing methods.

In this manner, the magnetic sensor 1 is manufactured. Note that impartation of the uniaxial magnetic anisotropy to the soft magnetic material layer 105 and/or magnetization of the thin film magnet 20 may be performed on the magnetic sensor 1 or plural magnetic sensors 1 after the process of dividing the magnetic sensor 1 into the individual magnetic sensors 1 shown in FIG. 7E.

Note that, in the case where the control layer 102 is not provided, it becomes necessary to impart the magnetic anisotropy in a plane by causing the crystal growth by heating the hard magnetic material layer 103 to not less than 800° C. after the hard magnetic material layer 103 was deposited. However, in the case where the control layer 102 is provided as in the magnetic sensor 1 to which the first exemplary embodiment is applied, since the crystal growth is accelerated by the control layer 102, the crystal growth caused by high temperature, such as not less than 800° C., is not required.

In addition, impartation of the uniaxial magnetic anisotropy to the first sensitive element 311 and the second sensitive element 312 may be performed in depositing the soft magnetic material layer 105, which is a Co alloy constituting the sensitive part 30, by use of a magnetron sputtering method, instead of being performed in the above-described heat treatment in the rotating magnetic field and heat treatment in the static magnetic field. In the magnetron sputtering method, a magnetic field is formed by using magnets and electrons generated by discharge are enclosed on a surface of a target. This increases collision probability of electrons and gases to accelerate ionization of gases, to thereby improve deposition rate of a film. By the magnetic field formed by the magnets used in the magnetron sputtering method, the soft magnetic material layer 105 is deposited, and at the same time, the uniaxial magnetic anisotropy is imparted to the soft magnetic material layer 105. By doing so, it is possible to omit the process of imparting the uniaxial magnetic anisotropy in the heat treatment in the rotating magnetic field and the heat treatment in the static magnetic field.

So far, the exemplary embodiment has been described; however, various modifications may be available without deviating from the gist of the present invention.

For example, the sensitive part 30 may be configured with plural soft magnetic material layers 105, the soft magnetic material layers being antiferromagnetically-coupled with a demagnetizing field suppressing layer composed of Ru or an Ru alloy interposed therebetween. This improves the magnetic impedance effect by the sensitive element part 31 (the first sensitive elements 311 and the second sensitive elements 312), and thereby improves the sensitivity of the magnetic sensor 1.

### REFERENCE SIGNS LIST

1 Magnetic sensor
10 Substrate
20 Thin film magnet
30 Sensitive part
31 Sensitive element part
32 Serial connection part
33 Terminal part
40, 40a, 40b Yoke
101 Adhesive layer
102 Control layer
103 Hard magnetic material layer
104 Dielectric layer
105 Soft magnetic material layer
311 First sensitive element
312 Second sensitive element

1.-4. (canceled)

5. A magnetic sensor comprising:
a non-magnetic substrate; and
a sensitive element part including a plurality of sensitive elements connected in parallel, each of the sensitive elements being provided on the substrate, being composed of a soft magnetic material, having a longitudinal direction and a short direction, being provided with uniaxial magnetic anisotropy in a direction crossing the longitudinal direction, and sensing a magnetic field by a magnetic impedance effect.

6. The magnetic sensor according to claim 5, wherein
the sensitive element part is provided in a plurality, and
the plurality of the sensitive element parts are arranged in the short direction with an interval and windingly connected in series.

7. The magnetic sensor according to claim 5, wherein the sensitive element part includes the plurality of sensitive elements arranged in the short direction with an interval, a width of the sensitive element in the short direction being smaller than the interval.

8. The magnetic sensor according to claim 6, wherein the sensitive element part includes the plurality of sensitive elements arranged in the short direction with an interval, a width of the sensitive element in the short direction being smaller than the interval.

9. The magnetic sensor according to claim 5, further comprising:
a thin film magnet laminated between the substrate and the sensitive element part and applying a magnetic field in the longitudinal direction of the sensitive element of the sensitive element part.

10. The magnetic sensor according to claim 6, further comprising:
a thin film magnet laminated between the substrate and the sensitive element part and applying a magnetic field in the longitudinal direction of the sensitive element of the sensitive element part.

11. The magnetic sensor according to claim 7, further comprising:
a thin film magnet laminated between the substrate and the sensitive element part and applying a magnetic field in the longitudinal direction of the sensitive element of the sensitive element part.

12. The magnetic sensor according to claim 8, further comprising:
a thin film magnet laminated between the substrate and the sensitive element part and applying a magnetic field in the longitudinal direction of the sensitive element of the sensitive element part.
